(19) United States
(12) Patent Application Publication
(10) Pub. No.: US 2004/0008496 A1
(43) Pub. Date: Jan. 15, 2004

(54) Portable thermal barrier for an electronic system

(76) Inventors: Thane Michael Larson, Roseville, CA (US); Christopher Gregory Malone, Folsom, CA (US)

Correspondence Address: HEWLETT-PACKARD COMPANY, Intellectual Property Administration, P.O. Box 272400, Fort Collins, CO, 80527-2400, US

(21) Appl. No.: 10/192,998

(22) Filed: Jul. 10, 2002

(51) Int. Cl. H05K 5/00; H05K 5/04; H05K 5/06

(52) U.S. Cl. 361/752

(57) ABSTRACT

The present invention is directed to a device, system and method for maintaining the thermal integrity of an operating electronic system. A thermal barrier comprises a rigid member configured to be attachable over an empty module receptacle in the electronic system. The thermal barrier further comprises at least one flexible member attached to the rigid member, the flexible member designed to form a thermal barrier between the electronic system and an ambient environment. In accordance with various embodiments of the thermal barrier, the flexible members form an interlaced teeth pattern, a symmetrical teeth pattern, or a single flap pattern. The thermal barrier is configured to be attachable over an opening in a chassis by means of a Velcro member, a magnetic member, a set of screws, or any other means of attaching the rigid body of the thermal barrier to the electronic system.

### FIELD OF THE INVENTION

The present invention relates generally to the field of electronics and, more specifically, to a device, system and method for maintaining the thermal integrity of an operating electronic system.

### BACKGROUND OF THE INVENTION

It is well known that electronic components generate heat as a result of their operation. As the generated heat increases above respective critical temperatures, failures can occur in the operation of these electronic components and therefore, the excess heat is typically dissipated to insure continued operation of these electronic components. As a result, the temperature of the ambient environment surrounding electronic systems is typically maintained below a specified critical operating temperature.

An electronic system typically maintains a low ambient-environment temperature by providing cooling mechanisms within the electronic-system housing. With the advent of replaceable components coupled with the need for continuous operation and redundancy of these electronic systems, a problem has arisen in situations where a technician needs to repair a failed electronic component or replace, i.e., hot swap, while the electronic system remains in operation. When the technician opens the housing to remove or repair a particular component, such as a rack-mount component from a rack-mount system, the opened housing may cause the temperature of the ambient environment to rise in some or all regions of the system because the cooling system was designed specifically for a closed environment. As a result, the higher ambient environment temperature can lead to system failure before the technician can complete the repairs or replacement and close the housing.

### SUMMARY OF THE INVENTION

According to one aspect of the present invention, a thermal barrier is provided for maintaining the thermal integrity of an operating electronic system that is being serviced. The thermal barrier is attachable to the electronic system and maintains the thermal integrity of the system while allowing a technician to access the system. For example, the thermal barrier may include a rigid member that attaches to the system and a flap attached to the rigid member. The flap maintains the thermal integrity of the system but allows the technician access to the system. For example, the flap may be analogous to the flexible flap that divides the baggage claim conveyor belt at the airport into baggage load and baggage claim regions.

By using a thermal barrier formed in accordance with the invention, a technician can maintain the thermal integrity of an operating system that is susceptible to ambient environment temperature change due to the housing being opened. An opening or set of opening in a system can be covered by a thermal barrier such that the ambient environment inside the electronic system remains closed while allowing a technician access to the inside of the electronic system. Furthermore, if a flexible member is used, it can be transparent such that a technician can also see into the inside of the electronic system without opening the member.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is an isometric view of an electronic system that is a suitable environment for an embodiment of the invention;

FIG. 2 is an isometric view of an electronic system wherein a module is being removed from the electronic system according to an embodiment of the invention;

FIG. 3 is an isometric view of an electronic system wherein a thermal barrier is being inserted into an empty module receptacle according to an embodiment of the invention;

FIG. 4A is a plan view of the thermal barrier of FIG. 3 according to an embodiment of the invention;

FIG. 4B is a plan view of the thermal barrier of FIG. 3 according to another embodiment of the invention;

FIG. 4C is a plan view of the thermal barrier of FIG. 3 according to another embodiment of the invention.

### DETAILED DESCRIPTION OF THE PREFERRED EMBODIMENT

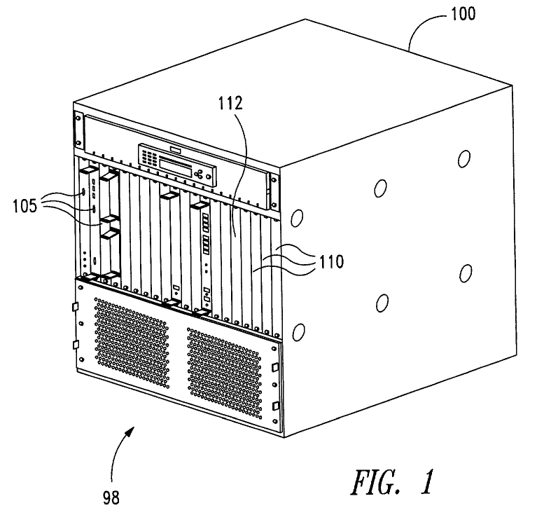

FIG. 1 is an isometric view of an electronic system 98 where an embodiment of the invention can be used during servicing of the system. The electronic system 98 has a chassis 100 that is capable of housing several rackmountable electronic components. In this example, the front face of the chassis has several electronic card slots 110 that are capable of interfacing with electronic-card components 105 that slide in and out of the electronic card slots 110. The electronic card slots 110 are typically of standardized sizes. One such standardized size is the 13U standard which is depicted in FIGS. 1-3. Other standards include 1U, 2U etc. and industrial 19″ racks. Each electronic-card slot 110 that does not have an electronic card component 105 inserted has a permanent thermal cover plate 112 over the electronic card slot 110 so that the thermal integrity of the electronic system is maintained.

The chassis 100 houses a temperature-control system (not shown) that maintains an operating temperature range for the ambient environment within the electronic system 98. Such temperature-control systems are well known in the art and will not be discussed further herein. When a thermal cover plate 112 or electronic card component 105 is removed from the electronic system 98 while it is operating, the thermal characteristics of the electronic system 98 may be disturbed. A temperature cooling system designed for certain thermal characteristics often cannot compensate for variations in the thermal characteristics that result because of an opening in the chassis 100. As a result of this imbalance, the operating temperature of the electronic system 98 could rise to system failure levels.

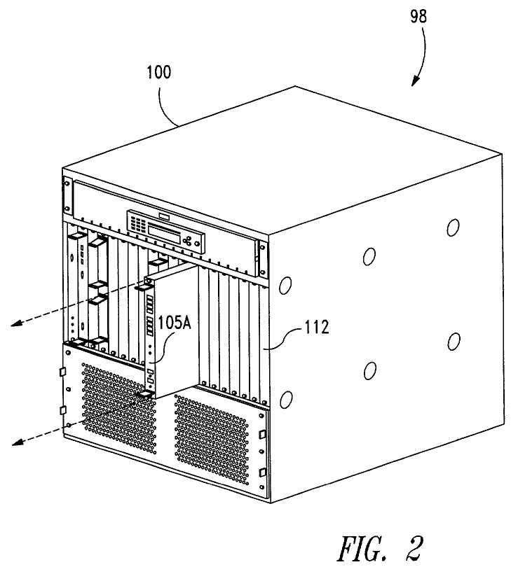

FIG. 2 is an isometric view of the electronic system 98 showing a particular electronic-card component 105a being removed from the chassis 100 for replacement or maintenance or to allow a technician to access the inside of the chassis 100. As pointed out previously, the opening left by the removed electronic-card component 105a may upset the thermal characteristics of the electronic system 98.

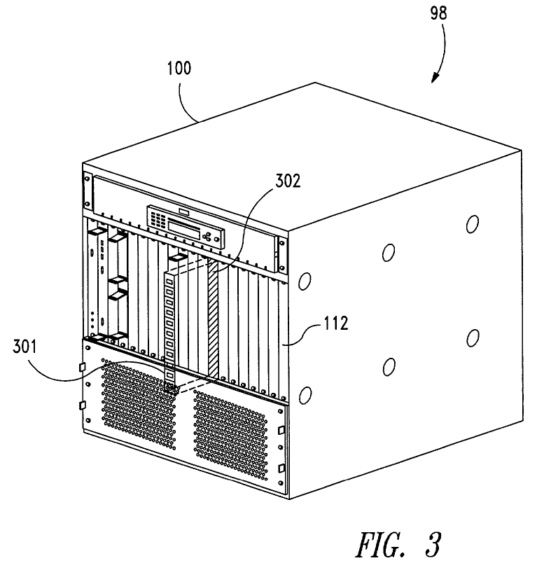

Referring to FIG. 3, to maintain the thermal integrity of the electronic system 98, a thermal barrier 301 is used to block the opening left in the chassis 100 by a removed electronic-card component 105a while a technician services the electronic system 98. For example, assume that a failed electronic-card component 105a is to be removed from the chassis 100 for repair. A technician would slide the failed electronic-card component 105a out of the chassis as depicted in FIG. 2. Once removed, there will be an empty electronic card slot 110 that, if left open, can eventually lead to system failure as the ambient environment temperature rises because the temperature control system was not designed to compensate for an opening 302. In the past, a technician might place a spare thermal cover plate 112 over the vacated space, but then the technician would not have access to the inside of the chassis 100 as may be required. A thermal barrier 301 formed in accordance with the present invention overcomes this problem.

The thermal barrier 301, described in more detail below, comprises a rigid outer body with flexible flaps that form an inner portion. The flexible flaps allow a technician to access the inside of the chassis 100 by penetrating the inner portion with an instrument such as a tool or hand (if the inner portion is large enough). After the technician removes the instrument, the flexible flaps return to a covering position as they are biased to do so. By having the thermal barrier 301 covering the opening 302, the thermal integrity of the electronic system 98 is maintained. Once the servicing is complete, the technician removes the thermal barrier 301 and replaces the failed electronic-card component 105a, or merely places a thermal cover plate 112 over the opening 302.

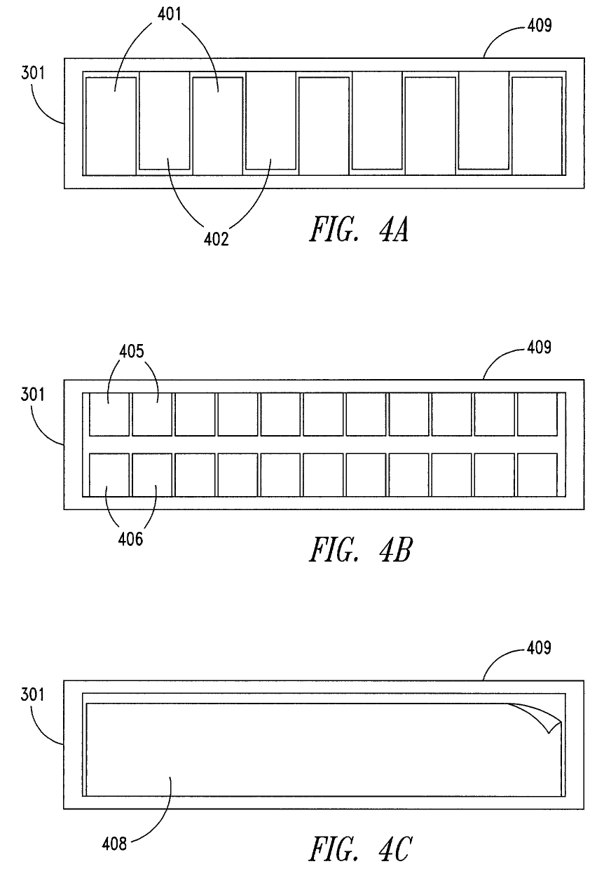

There are a number of possible embodiments of the thermal barrier 301. Three of these embodiments are depicted in the FIGS. 4A-4C.

The thermal barrier 301 has an outer rigid body 409, which is typically made of a hard plastic composite, but can alternatively be made of any rigid material, including metal, wood, etc. The outer rigid body 409 is shaped to be attachable to the chassis 100 so as to cover one or more electronic-card component opening 302(FIG. 2). In one embodiment, the thermal barrier 301 has a magnetic means that allows the thermal barrier 301 includes magnets (not shown) that attach the rigid body 409 to the chassis 100, or to another portion of the electronic system 98. Alternatively, the rigid body 409 can be magnetized or other fasteners, such as Velcro, screws or adhesive can be used to attach the thermal barrier 301 to the chassis 100.

Still referring to FIG. 3, one or more flexible flaps 402 are attached to the rigid body 409. The flaps 402 allow a technician to poke an instrument through the thermal barrier 301 while at the same time maintaining the thermal integrity of the electronic system 98 as other flexible flaps not pushed in remain in place. The flexible flaps 402 are typically made from overlapping plastic or other flexible material. Therefore, when the technician is not poking an instrument through the flexible flaps 402, the flexible flaps 402 lay relatively flat against one another to provide a thermal barrier. Additionally, the flexible flaps 402 may be or transparent such that a technician can see into the chassis 100 when the flexible flaps 402 are closed. Although the thermal barrier 301 may not be airtight, it does significantly restrict airflow between the inside and the outside of the chassis 100. Alternatively, the flexible flaps 402 may include magnets or may be made from sticky silicon rubber so that they effectively self seal to one another when in the biased closed position. Self sealing of the flexible flaps 402 further increases the seal provided by the thermal barrier 301.

Referring to FIG. 4A, one embodiment of the thermal barrier 301 includes flexible flaps 402 that form an interlaced teeth pattern. This pattern is characterized by a first set of flexible flaps 401 emanating from one longitudinal side of the outer rigid body 409 and a second set of flexible flaps 402 emanating from the other longitudinal side of the outer rigid body 409. The pattern is further characterized by each flexible flap extending the full width of the outer rigid body 409 such that each flexible flap reaches the opposite longitudinal side of the outer rigid body 409. Furthermore, each flexible flap is spaced apart from other flexible flaps on the same longitudinal side such that flexible flaps emanating from the opposite longitudinal side do not overlap each other as characterized in FIG. 4A. Alternatively, the flexible flaps 401, 402 may overlap to provide a better thermal seal. The number and width of flexible flaps varies with the different standards by which the thermal barrier 301 is designed to interface.

FIG. 4B shows another embodiment of the thermal barrier 301. In this embodiment, again the thermal barrier 301 is shaped in accordance with any number of standards as described above. However, the flexible flap pattern in this embodiment is a symmetrical teeth pattern. Again, in this embodiment there is a first set of flexible flaps 405 and a second set of flexible flaps 406. A symmetrical teeth pattern is characterized by flexible flaps emanating from both longitudinal sides of the outer rigid body such that each flexible flap on one longitudinal side has and equally-shaped, reciprocal flexible flap emanating from the opposite longitudinal side as illustrated in FIG. 4B. The flexible flaps 405, 406 may or may not overlap.

FIG. 4C shows yet another example of a thermal barrier 301 formed in accordance with the invention. Once again, in this embodiment, the thermal barrier 301 is shaped in accordance with any number of standards as described above. In this example, a single flap pattern, there is just one flexible flap 408 emanating from one longitudinal side of the outer rigid body 409.

Other flap patterns (not shown) in thermal barrier 301 may also be formed in accordance with the present invention. Amy number of flaps, in any pattern designed to maintain a thermal barrier between the inside and the outside of a chassis 100 can be realized in accordance with the invention.

While the preferred embodiment of the invention has been illustrated and described, it will be appreciated that various changes can be made herein without departing from the spirit and scope of the invention.

The embodiments of the invention in which an exclusive property or privilege is claimed are defined as follows:

1. A thermal barrier for an electronic system comprising:
i) a member configured to be attachable over an open space in a housing of the electronic system; and
ii) at least one movable member attached to the rigid member, the movable member biased to form a penetrable thermal barrier between an interior ambient environment of the electronic system and an exterior ambient environment.

2. The thermal barrier of claim 1, wherein the open space that the rigid member is configured to be attachable over is at least one empty electronic module receptacle.

3. The thermal barrier of claim 1, wherein the movable member forms an interlaced teeth pattern.

4. The thermal barrier of claim 1, wherein the movable member forms a symmetrical teeth pattern.

5. The thermal barrier of claim 1, wherein the movable member forms a single flap pattern.

6. The thermal barrier of claim 1, wherein the movable member is transparent.

7. An electronic system comprising:
i) a chassis having at least one opening; and
ii) a thermal barrier configured over be attachable to the at least one opening for an electronic module in the electronic system comprising:
a) a rigid member; and
b) at least one flexible member attached to the rigid member, the flexible member biased to form a penetrable thermal barrier between an interior ambient environment of the electronic system and an exterior ambient environment.

8. The electronic system of claim 7, wherein the rigid member is configured to be attachable to the opening by means of a magnetic member.

9. The electronic system of claim 7, wherein the rigid member is configured to be attachable to the opening by means of a Velcro member.

10. The electronic system of claim 7, wherein the rigid member is configured to be attachable to the opening by a set of screws.

11. The electronic system of claim 7, wherein the thermal barrier is configured to be attachable over multiple openings in the electronic system.

12. A method for maintaining the thermal integrity of an electronic system comprising:
i) removing a portion of a chassis of the electronic system, such that an opening is resultant;
ii) attaching a thermal barrier over the opening, the thermal barrier comprising:
a) a rigid member configured to be attachable over an opening in the chassis of the electronic system; and
b) at least one flexible member attached to the rigid member, the flexible member biased to form a penetrable thermal barrier between an interior ambient environment of the electronic system and an exterior ambient environment.

13. The method of claim 12, wherein attaching the thermal barrier over the opening further comprises adjusting the thermal barrier such that airflow between an interior environment of the electronic system and the exterior environment is restricted.
